(19) United States
(12) Patent Application Publication
(10) Pub. No.: US 2008/0230913 A1
(43) Pub. Date: Sep. 25, 2008

(54) Stackable semiconductor device and fabrication method thereof

(75) Inventors: Chien-Ping Huang, Taichung (TW); Chin-Huang Chang, Taichung Hsien (TW); Chih-Ming Huang, Hsinchu Hsien (TW); Chun-Chi Ke, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/077,223

(22) Filed: Mar. 18, 2008

(30) Foreign Application Priority Data
Mar. 20, 2007 (TW) 096109442

(51) Int. Cl. H01L 23/488; H01L 21/304

(52) U.S. Cl. 257/762; 438/113; 257/E21.268; 257/E23.023

(57) ABSTRACT

The invention provides a stackable semiconductor device and a fabrication method thereof, including providing a wafer having a plurality of dies mounted thereon, both the die and the wafer having an active surface and a non-active surface opposing one another respectively, wherein each die has a plurality of solder pads formed on the active surface thereof and a groove formed between adjacent solder pads to form a first metal layer therein that is electrically connected to the solder pads; subsequently thinning the non-active surface of the wafer to where the grooves are located to expose the first metal layer therefrom, and forming a second metal layer on the non-active surface of the wafer for electrically connecting with the first metal layer; and separating the dies to form a plurality of stackable semiconductor devices. Thereby, the first and second metal layers formed on the active surface and the non-active surface of the semiconductor device can be stacked and connected to constitute a multi-die stack structure, thereby increasing integration without increasing the area of the stacked dies. Further, the problems known in the prior art of poor electrical connection, complicated manufacturing process and increased cost as a result of using wire bonding and TSV can be avoided.

### FIELD OF THE INVENTION

The present invention relates to a semiconductor device and a fabrication method thereof, and more particularly, to a vertically stackable semiconductor device and a fabrication method thereof.

### BACKGROUND OF THE INVENTION

As the need for portable electronic products and associated products (e.g. in communication, network and computer applications) to become more compact and lighter increases, accompanied by the trend for multi-functional and high-performance electronic devices, conventional semiconductor packages are manufactured in Multichip Module (MCM) to achieve high integration and miniaturization, wherein at least two dies are attached to a substrate (or lead frame) of a single package.

Referring to FIG. 1, a conventional semiconductor package having a plurality of horizontally spaced dies is depicted. This semiconductor package includes a substrate 100, a first die 110 having an active face 110a electrically connected to the substrate 100 via a first wire 120 and an opposite non-active face 110b attached to the substrate 100 and a second die 140, spaced apart from the first die, having an active face 140a electrically connected to the substrate 100 via a second wire 150 and an opposite non-active face 140b attached to the substrate 100.

In the above conventional semiconductor package, the dies have to be spaced with a certain distance in order to avoid the wires between the dies to be in contact with each other. As such, a considerable large die attachment area has to be provided for multi-die designs; this will result in cost increase and limitation in size reduction.

Referring now to FIG. 2, a stacked semiconductor package disclosed in U.S. Pat. No. 6,538,331 is depicted. A second die 240 is stacked on a first die 210 on a substrate 200. In particular, the upper die is stacked by an offset with respect to the underlying die such that the wires 220 and 250 of the first and second dies 210 and 240, respectively, can be disposed easily on the substrate 200.

This method saves more space than the conventional semiconductor package with horizontally arranged dies. However, it still requires the use of bonding wires to electrically connect the dies and the substrate. As a result, the quality of electrical connection may be adversely affected by the length of the wires. Moreover, since the dies still have to be offset to some extent to allow wire bonding, the die attachment area cannot be minimized.

In view of this, U.S. Pat. Nos. 6,642,081, 5,270,261 and 6,809,421 disclose various Through Silicon Via (TSV) techniques that allow vertical stacking and electrically connection of a plurality of dies. However, these techniques require complicated and expansive manufacturing processes.

Therefore, there is a need for a multi-die stackable structure and a fabricating method thereof that minimizes the area of the stacked dies while still achieves high integration, avoids poor electrical quality due to wire bonding and reduces cost and complication of the TSV techniques.

### SUMMARY OF THE INVENTION

In the light of forgoing drawbacks, an objective of the present invention is to provide a stackable semiconductor device and a fabrication method thereof that enables integration of multiple dies in a single semiconductor package without increasing the area of the stacked dies.

Another objective of the present invention is to provide a stackable semiconductor device and a fabrication method thereof that is simpler and cheaper to implement than the conventional TSV technique.

Still another objective of the present invention is to provide a stackable semiconductor device and a fabrication method thereof that allows a plurality of semiconductor dies to directly electrically connect each other, avoiding poor electrical quality associated with the conventional wire bonding technique.

Yet another objective of the present invention is to provide a stackable semiconductor device and a fabrication method thereof that enables direct vertical stacking of a plurality of semiconductor dies

In accordance with the above and other objectives, the present invention discloses a method for fabricating a stackable semiconductor device, comprising: providing a wafer with a plurality of dies having an active face and an opposite non-active face, a plurality of solder pads disposed on the active face and grooves formed between the neighboring solder pads; forming in the grooves a first metal layer electrically connected to the solder pads; thinning the non-active to where the grooves are located to expose the first metal layer from the non-active face; disposing an insulating layer on the non-active face with at least one opening for exposing the first metal layer; forming in the at least one opening a second metal layer electrically connected to the first metal layer; and separating the dies to form a plurality of stackable semiconductor devices.

Subsequently, the second metal layer on the non-active face of one semiconductor device can be stacked and electrically connected to the first metal layer on the active face of another semiconductor device, thereby forming a stacked multi-die structure.

With the above fabrication method, the present invention further discloses a stackable semiconductor device, comprising: a die having an active face with a plurality of solder pads disposed thereon and an opposite non-active face; a first metal layer disposed around the edges of the active face and the sides of the die and electrically connected to the solder pads; an insulating layer covering the non-active face with at least one opening on an edge of the non-active face for exposing the first metal layer; and a second metal layer formed in the at least one opening of the insulating layer and electrically connected to the first metal layer.

Therefore, the stackable semiconductor device and the fabrication method according to the present invention essentially provide a wafer with a plurality of dies thereon having an active face and an opposite non-active face. Each die has a plurality of solder pads formed on the active face. Grooves are formed between neighboring solder pads, allowing a first metal layer electrically connected to the solder pads to be formed in the grooves. The non-active of the wafer is then thinned to expose the first metal layer. A second metal layer electrically connected to the first metal layer is formed on the non-active face. Thereafter, the dies are singulated to form a plurality of stackable semiconductor devices.

Subsequently, the second metal layer on the non-active face of a first semiconductor device can be attached and electrically connected to a die carrier, while the second metal layer on the non-active face of a second semiconductor device can be attached and electrically connected to the first metal layer on the active face of the first semiconductor device, thereby obtaining a stackable multi-die structure. In this way, a plurality of dies can be vertically stacked on one another to increase electrical functionalities while not increasing the area of the stacked dies, at the same time avoiding poor electrical quality associated with the conventional wire bonding technique and complexity and high cost involved with TSV technique.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view depicting a conventional semiconductor package having a plurality of horizontally spaced dies;

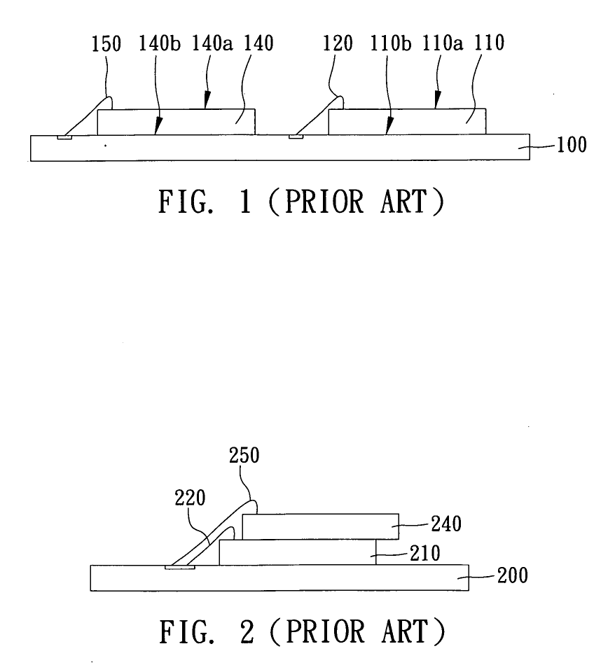

FIG. 2 is a cross-sectional view depicting a semiconductor package with stacked dies as disclosed in U.S. Pat. No. 6,538,331;

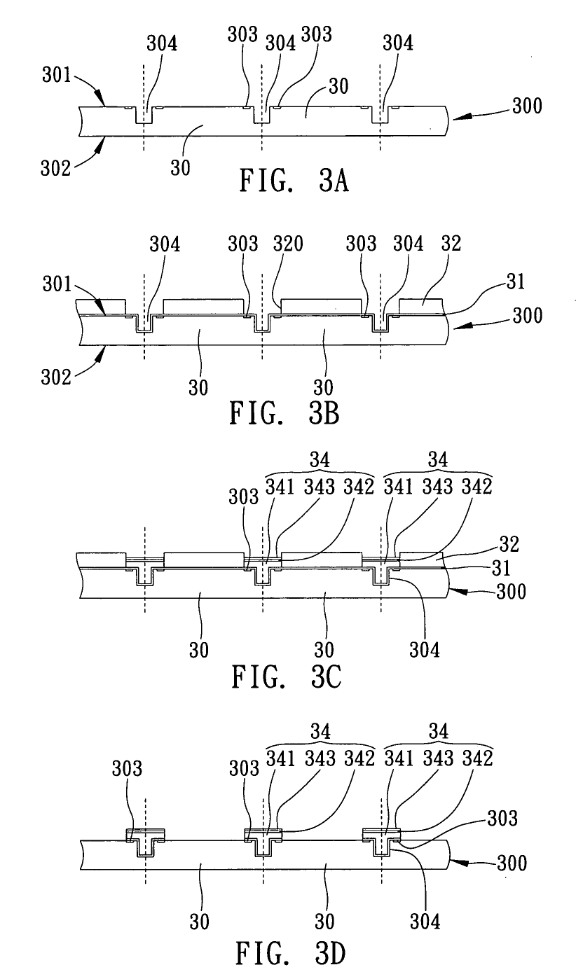

FIGS. 3A to 3I are cross-sectional views depicting a stackable semiconductor device and a fabrication method thereof according to a first embodiment of the present invention;

FIG. 4 is a cross-sectional view illustrating stacking of semiconductor devices according to an embodiment of the present invention;

FIG. 5 is a cross-section view of a stackable semiconductor device according to a second embodiment of the present invention; and

FIGS. 6A to 6D are cross-sectional views depicting a stackable semiconductor device and a fabrication method thereof according to a third embodiment of the present invention.

### DETAILED DESCRIPTION OF THE EMBODIMENTS

The present invention is described by the following specific embodiments. Those with ordinary skills in the arts can readily understand the other advantages and functions of the present invention after reading the disclosure of this specification. The present invention can also be implemented with different embodiments. Various details described in this specification can be modified based on different viewpoints and applications without departing from the scope of the present invention.

### First Embodiment

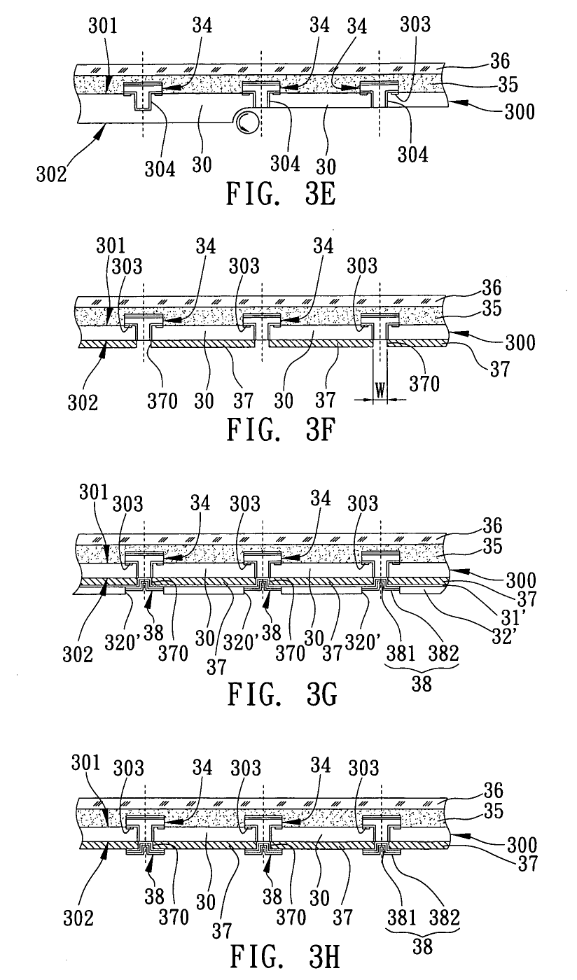

Referring to FIGS. 3A to 3I, a stackable semiconductor device and a fabrication method thereof according to a first embodiment of the present invention is depicted.

As shown in FIG. 3A, a wafer 300 with a plurality of dies 30 is provided. The dies 30 and the wafer 300 have an active face 301 and a non-active face 302. A plurality of solder pads 303 is disposed on the active face 301 of the dies 30. Grooves 304 are formed between two neighboring solder pads 303.

As shown in FIGS. 3B to 3D, a conductive layer 31 is formed on the active face 301 using methods such as sputtering. The conductive layer 31 can be made of materials such as Ti/Cu, TiW/Cu, TiW/Au, Al/NiV/Cu, NiV/Cu, Ti/NiV/Cu or TiW/NiV/Cu. Then, a resist layer 32 is further formed on the conductive layer 31 with a plurality of openings 320 that correspondingly expose the grooves 304.

Then, electroplating is performed to form a first metal layer 34 in the grooves 34 inside the resist openings 320. The first metal layer 34 consists of materials such as a thick layer of copper (about 10˜30 m) 341, a nickel layer (about 2˜5 m) 342 and a tin layer 343. The first metal layer 34 is electrically connected to the solder pads 303.

Then, the resist layer 32 and the underlying conductive layer 31 are removed.

As shown in FIG. 3E, the active face 301 of the wafer 300 are attached to a carrier 36 (e.g. glass) through an adhesive layer 35 and the non-active face 302 of the wafer 300 are thinned to where the grooves 304 are located, such that the first metal layer 34 are exposed from the non-active face 302. The thickness of the wafer 300 after thinning is about 25˜75 m.

As shown in FIG. 3F, an insulating layer 37 is disposed on the non-active face 302 with openings 370 to expose the first metal layer 34. The insulating layer 37 may be formed for example from Benzo-Cyclo-Butene (BCB) or polyimide with a thickness of 5 m. Preferably, the width W of the openings 370 is slightly smaller than that of the grooves 304.

As shown in FIGS. 3G and 3H, a conductive layer 31′ (e.g. made of Ti/Cu or TiW/Cu) is further formed on the non-active face 302 of the wafer 300 and the insulating layer 37 by methods such as sputtering. A resist layer 32′ is then formed on the conductive layer 31′ with openings 320′ formed to expose the conductive layer 31′.

Then, through electroplating, a second metal layer 38 consisted of nickel or copper 381 and soldering tin 382 is formed in the resist openings 320′, so that the second metal layer 38 is electrically connected to the first metal layer 34. Thereafter, the resist layer 32′ and the underlying conductive layer 31′ are removed.

As shown in FIG. 3I, the carrier 36 and the adhesive layer 35 are removed and the wafer 300 is cut to separate the dies 30, thus forming a plurality of stackable semiconductor devices.

With the above fabrication method, the present invention discloses a stackable semiconductor device, including: a die 30 having an active face 301 with a plurality of solder pads 303 formed thereon and an opposite non-active face 302; a first metal layer 34 disposed around the edges of the active face 301 extending to the sides of the die 30 and electrically connected with the solder pads 303; an insulating layer 37 covered the non-active face 302 with openings formed at the edges of the non-active 302 for exposing the corresponding first metal layer 34; and a second metal layer 38 formed in the openings of the insulating layer 37 and electrically connected to the first metal layer 34.

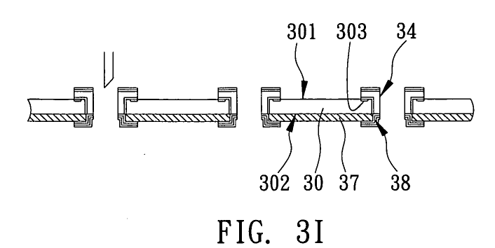

Referring to FIG. 4, two semiconductor devices stacked tougher are shown, in which the soldering material of the second metal layer 38 on the non-active face 302 of one semiconductor device is reflowed to stack and electrically connect onto the soldering material of the first metal layer 34 on the active face 301 of the other semiconductor device, thereby forming a stacked multi-die structure. Alternatively, thermal compression can be directly applied to obtain the above multi-die structure, in which the second metal layer of one semiconductor device is thermally compressed and electrically connected to the first metal layer of the other semiconductor device.

### Second Embodiment

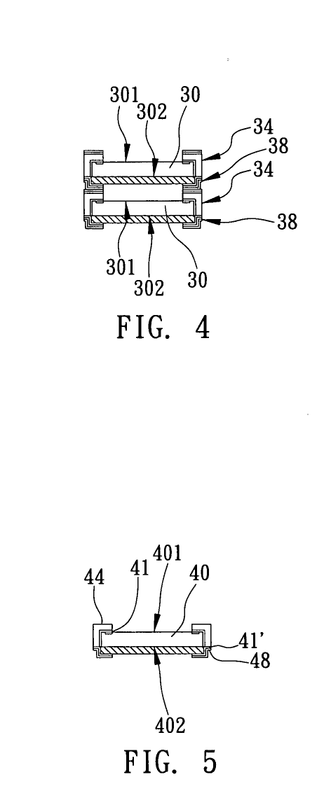

Referring to FIG. 5, a cross-section view of a stackable semiconductor device according to a second embodiment of the present invention is depicted. The semiconductor device of this embodiment is similar to that of the previous embodiment, the main difference being that the first metal layer 44 electroplated on the active face 401 of the die 40 is made of gold (Au), facilitated by pre-sputtering the conductive layer 41 (e.g. TiW/Au) on the active face 401. It has a thickness of about 15˜30 m. Additionally, the second metal layer 48 electroplated on the non-active face 402 is made of tin (Sn) or gold (Au), facilitated by pre-sputtering the conductive layer 41′ (e.g. Ti/Cu, TiW/Cu or TiW/Au) on the non-active face 402. It has a thickness of about 20˜40 m.

As a result, during stacking, the second metal layer (e.g. tin) of one semiconductor device can be directly thermally compressed onto the first metal layer (e.g. gold) of another semiconductor device, thus forming a eutectic structure and simplifying the fabrication processes.

Therefore, the stackable semiconductor device and the fabrication method thereof according to the present invention essentially provides a wafer with a plurality of dies thereon having an active face and an opposite non-active face. The active faces of the dies each has a plurality of solder pads formed thereon. Grooves are formed between neighboring solder pads, allowing a first metal layer electrically connected to the solder pads to be formed in the grooves. The non-active of the wafer is then thinned to expose the first metal layer. A second metal layer electrically connected to the first metal layer is formed on the non-active face. Thereafter, the dies are singulated to form a plurality of stackable semiconductor devices. Subsequently, the second metal layer on the non-active face of a second semiconductor device can be attached and electrically connected to the first metal layer on the active face of a first semiconductor device, thereby obtaining a stackable multi-die structure. In this way, a plurality of dies can be vertically stacked on one another to increase electrical functionalities while not increasing the area of the stacked dies and avoiding poor electrical quality associated with the conventional wire bonding technique and complexity and high cost involved with TSV technique.

### Third Embodiment

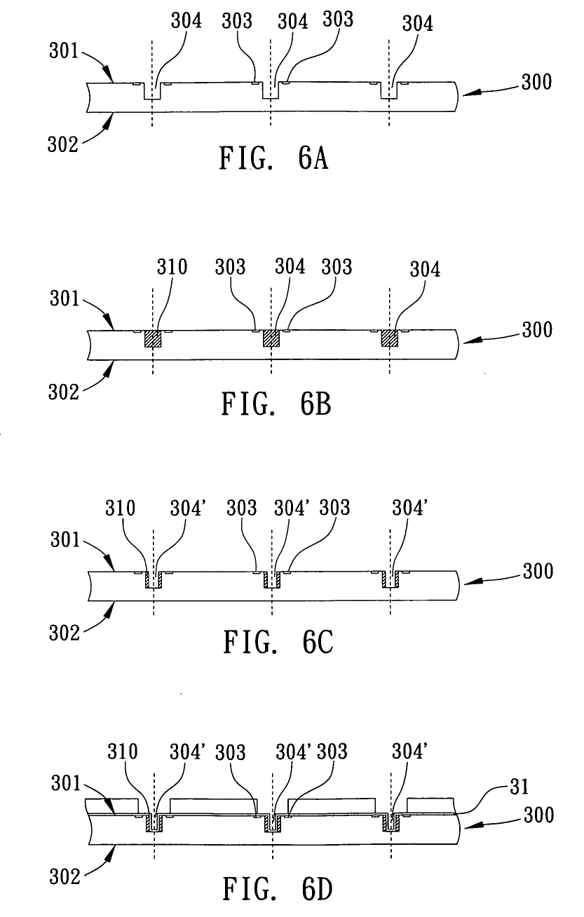

Referring to FIGS. 6A to 6D, a cross-section view of a stackable semiconductor device according to a third embodiment of the present invention is depicted. For simplicity, elements in this embodiment that are the same or similar to those in the first embodiment are designated by the same reference number.

The semiconductor device of this embodiment is similar to that of the first embodiment, the main difference being that, after forming grooves 304 between the adjacent solder pads 303, an insulating layer of polymer gel 310 is further formed in the grooves 304. The polymer gel 310 forms dents 304′. Then, a conductive layer 31 is formed on the active face 301 of the wafer 300, the dents 304′ and in the grooves 304, thus forming the polymer gel 310 between the die 30 and the conductive layer 31. The polymer gel 310 can be made of materials such as polyimide (PI) or benzocyclobutene (BCB). The polymer gel 310 increases insulation and adhesion between the die 30 and the conductive layer 31. Thereafter, subsequent processes can be carried out as those described in the first embodiment to form a plurality of stackable semiconductor devices.

The above embodiments are only used to illustrate the principles of the present invention, and they should not be construed as to limit the present invention in any way. The above embodiments can be modified by those with ordinary skills in the arts without departing from the scope of the present invention as defined in the following appended claims.

What is claimed is:

1. A method for fabricating a stackable semiconductor device, comprising the steps of:
providing a wafer with a plurality of dies having an active face and an opposite non-active face, a plurality of solder pads disposed on the active face and grooves formed between the neighboring solder pads;
forming in the grooves a first metal layer electrically connected to the solder pads;
thinning the non-active face to where the grooves locate to expose the first metal layer from the non-active face;
disposing an insulating layer on the non-active face with at least one opening for exposing the first metal layer;
forming in the at least one opening a second metal layer electrically connected to the first metal layer; and
separating the dies to form a plurality of stackable semiconductor devices.

2. The method of claim 1, wherein a method for forming the first metal layer includes the steps of:
forming a conductive layer on the active face;
applying on the conductive layer a resist layer with a plurality of openings corresponding to the grooves;
performing electroplating to form the first metal layer in the openings at the locations of the grooves, the first metal layer electrically connected to the solder pads; and
removing the resist layer and the underlying conductive layer.

3. The method of claim 2, wherein the conductive layer is selected from the group consisting of Ti/Cu, TiW/Cu, TiW/Au, Al/NiV/Cu, NiV/Cu, Ti/NiV/Cu and TiW/NiV/Cu.

4. The method of claim 2, wherein the first metal layer includes a thick copper layer, a nickel layer and a soldering material.

5. The method of claim 2, wherein the first metal layer includes gold.

6. The method of claim 1, wherein, before the non-active face is thinned, the active face is attached to a carrier through an adhesive layer to facilitate thinning of the non-active face to the grooves.

7. The method of claim 1, wherein a method for forming the second metal layer includes the steps of:
forming a conductive layer on the non-active face and the insulating layer;
applying on the conductive layer a resist layer with a plurality of openings to expose the openings of the insulating layer;
performing electroplating to form the second metal layer in the openings of the resist layer, the second metal layer electrically connected to the first metal layer; and
removing the resist layer and the underlying conductive layer.

8. The method of claim 7, wherein the conductive layer formed on the non-active face and the insulating layer is selected from the group consisting of Ti/Cu, TiW/Cu, TiW/Au, Al/NiV/Cu, NiV/Cu, Ti/NiV/Cu and TiW/NiV/Cu.

9. The method of claim 7, wherein the second metal layer includes a nickel layer, a copper layer and a soldering material.

10. The method of claim 7, wherein the second metal layer includes a tin layer.

11. The method of claim 1, further comprising stacking and electrically connecting the second metal layer on the non-active face of one semiconductor device to the first metal layer on the active face of another semiconductor device, thereby forming a stacked multi-die structure.

12. The method of claim 11, wherein the electrically connection between the first and second metal layers is achieved through reflow or thermal compression that forms a eutectic structure.

13. The method of claim 1, further comprising forming an insulating layer of polymer gel in the grooves after forming grooves between the adjacent solder pads, forming dents from the polymer gel and forming the first metal layer on the active face of the wafer and the dents.

14. The method of claim 13, wherein the polymer gel is made of one of polyimide (PI) and benzocyclobutene (BCB).

15. A stackable semiconductor device, comprising:
a die having an active face with a plurality of solder pads disposed thereon and an opposite non-active face;
a first metal layer disposed around the edges of the active face and the sides of the die and electrically connected to the solder pads;
an insulating layer covering the non-active face with at least one opening on an edge of the non-active face for exposing the first metal layer; and
a second metal layer formed in the at least one opening of the insulating layer and electrically connected to the first metal layer.

16. The device of claim 15, wherein a conductive layer is disposed between the first metal layer and the die.

17. The device of claim 16, wherein the conductive layer is selected from the group consisting of Ti/Cu, TiW/Cu, TiW/Au, Al/NiV/Cu, NiV/Cu, Ti/NiV/Cu and TiW/NiV/Cu.

18. The device of claim 15, wherein the first metal layer includes a thick copper layer, a nickel layer and a soldering material.

19. The device of claim 15, wherein the first metal layer includes gold.

20. The device of claim 15, wherein a conductive layer is disposed between the second metal layer and the die.

21. The device of claim 20, wherein the conductive layer is made of Ti/Cu or TiW/Cu.

22. The device of claim 15, wherein the second metal layer includes a nickel layer, a copper layer and a soldering material.

23. The device of claim 15, wherein the second metal layer includes a tin layer.

24. The device of claim 15, further comprising another semiconductor device, wherein the second metal layer on the non-active face of the another semiconductor device is stacked and electrically connected to the first metal layer on the active face of the semiconductor device, thereby forming a stacked multi-die structure.

25. The device of claim 24, wherein the electrically connection between the first and second metal layers is achieved through reflow or thermal compression that forms a eutectic structure.

26. The device of claim 15, wherein an insulating layer of polymer gel is further formed between the first metal layer and the die.

27. The device of claim 26, wherein the polymer gel is made of one of polyimide (PI) and benzocyclobutene (BCB).
